(19) United States
(12) Patent Application Publication
(10) Pub. No.: US 2006/0107147 A1
(43) Pub. Date: May 18, 2006

(54) Semiconductor device with timing correction circuit

(75) Inventors: Tetsuji Tsutsumi, Kasugai (JP); Kiyoshi Niikawa, Kasugai (JP); Michio Haba, Kasugai (JP); Yuichi Akaba, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/039,933

(22) Filed: Jan. 24, 2005

(30) Foreign Application Priority Data
Oct. 26, 2004 (JP) 2004-311422

(51) Int. Cl. G01R 31/28

(52) U.S. Cl. 714/731

(57) ABSTRACT

A semiconductor device includes a timing correction circuit coupled to an external terminal for receiving an input data signal to change a relative timing between the input data signal and an internal clock signal to generate a plurality of relative latch timings to latch one of the input data signal and the internal clock signal in response to the other one of the input data signal and the internal clock signal, thereby selecting an optimal relative latch timing according to a result of the latching, and a latch circuit coupled to the timing correction circuit to latch the input data signal with the optimal relative latch timing.

### BACKGROUND OF THE INVENTION

1. Field of the Invention

The present invention generally relates to semiconductor devices, and particularly relates to a semiconductor device which latches signals in response to a timing signal as the signals are supplied from an exterior.

2. Description of the Related Art

In designing semiconductor devices implementing LSI circuits, AC specifications inclusive of the setup time, hold time, etc., are defined in advance in accordance with the product specifications. Timing checks are conducted by use of a CAD (computer aided design) at the design stage. To be specific, a timing check is performed based on the layout of a designed logic circuit, and, upon finding a problem, the layout is modified with respect to the circuit portion relating to the timing problem. A further timing check is carried out after the layout modification. If a problem is found again by the timing check, the circuit portion of the layout relating to the problem is modified. Timing checks and layout modifications are repeated until the design of the logic circuit is finalized without any timing violation.

As the operating speed of semiconductor devices increases, it becomes increasingly difficult to secure sufficient margins for AC specifications. Without sufficient margins, the products are treated as defective even if there is slight product variation. This results in difficulty improving the product yield rate.

Even if not rejected as being defective, such products have an input/output interface for inputting/outputting data signals, and there is delay variation in such an input/output interface to some extent due to product variation. Under the condition of high operating frequency, no sufficient margin exists with respect to AC specifications. If there is delay variation in the input/output interface, thus, requirements for the setup time and hold time of input signals and the maximum delay of output signals may not be satisfied with respect to data exchange between chips. The data exchange between chips may thus fail, especially when there is a difference in signal propagation time caused by difference in the length of wire paths between the chips, or when there is an increase in the load caused by multiple chips connected to a single output node.

Accordingly, there is a need for a semiconductor device which can receive data correctly by correcting signal delays at the input/output interface portion of the chip after the chip is implemented on a board with wires connected to other chips.

### SUMMARY OF THE INVENTION

It is a general object of the present invention to provide a semiconductor device that substantially obviates one or more problems caused by the limitations and disadvantages of the related art.

Features and advantages of the present invention will be presented in the description which follows, and in part will become apparent from the description and the accompanying drawings, or may be learned by practice of the invention according to the teachings provided in the description. Objects as well as other features and advantages of the present invention will be realized and attained by a semiconductor device particularly pointed out in the specification in such full, clear, concise, and exact terms as to enable a person having ordinary skill in the art to practice the invention.

To achieve these and other advantages in accordance with the purpose of the invention, the invention provides a semiconductor device, which includes a timing correction circuit coupled to an external terminal for receiving an input data signal to change a relative timing between the input data signal and an internal clock signal to generate a plurality of relative latch timings to latch one of the input data signal and the internal clock signal in response to the other one of the input data signal and the internal clock signal, thereby selecting an optimal relative latch timing according to a result of the latching, and a latch circuit coupled to the timing correction circuit to latch the input data signal with the optimal relative latch timing.

According to at least one embodiment of the present invention, a relative timing difference between the input data signal and the internal clock signal is progressively changed to generate a plurality of timing relationships, and an optimal timing relationship is selected in response to the result of latching operations using the plurality of timing relationships. This makes it possible to latch the input data under the condition that the relative timing between the input data signal and the internal clock signal is optimum. In so doing, the internal clock signal is relatively delayed to provide for a sufficient setup time, or is relatively advanced to provide for a sufficient hold time. With this provision, it is possible to receive data correctly by correcting signal delays at the input/output interface portion of the chip after the chip is implemented on a board with wires connected to other chips.

### BRIEF DESCRIPTION OF THE DRAWINGS

Other objects and further features of the present invention will be apparent from the following detailed description when read in conjunction with the accompanying drawings, in which:

FIG. 1 is a block diagram showing a first embodiment of a semiconductor device according to the present invention;

FIG. 2 is a timing chart for explaining the operation of the semiconductor device shown in FIG. 1;

FIG. 3 is a block diagram showing a second embodiment of the semiconductor device according to the present invention; and

FIG. 4 is a timing chart for explaining the operation of the semiconductor device shown in FIG. 3.

### DESCRIPTION OF THE PREFERRED EMBODIMENTS

In the following, embodiments of the present invention will be described with reference to the accompanying drawings.

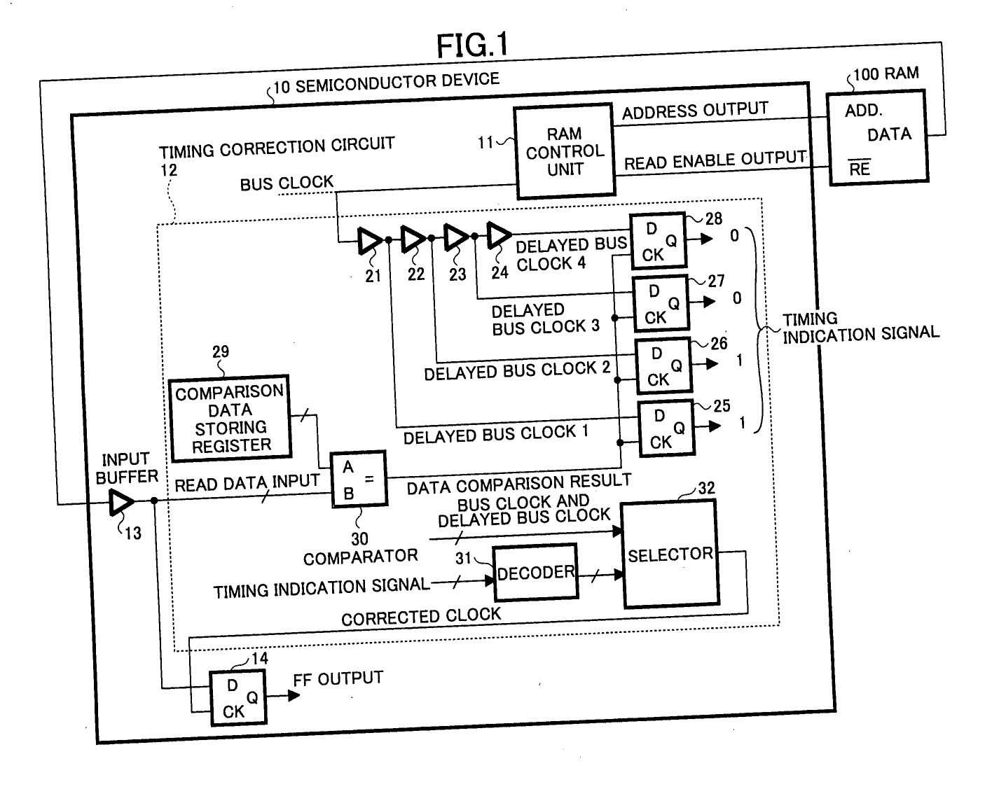

FIG. 1 is a block diagram showing a first embodiment of a semiconductor device according to the present invention. The configuration shown in FIG. 1 is designed for a CPU or a memory driver device such as a memory controller that receives data obtained by accessing a semiconductor memory device. It should be noted, however, that the present invention is applicable to any types of semiconductor devices as long as the devices are provided with the function to receive data in synchronization with a clock signal.

A semiconductor device 10 of FIG. 1 includes a RAM control unit 11, a timing correction circuit 12, an input buffer 13, and a latch circuit 14. The semiconductor device 10 is connected to a semiconductor memory device (RAM) 100. The RAM control unit 11 of the semiconductor device 10 supplies an address signal and a read enable signal to the semiconductor memory device 100, thereby reading data from the address specified by the address signal. The read data is supplied to the input buffer 13 of the semiconductor device 10 through a data bus. The input buffer 13 supplies the received read data to the timing correction circuit 12 and to the latch circuit 14. The latch circuit 14 may be comprised of flip-flops, which latch the data on a bit-by-bit basis in response to a clock input CK.

The timing correction circuit 12 receives a bus clock signal supplied from the RAM control unit 11 and the input data (RAM read data) supplied from the input buffer 13. The timing correction circuit 12 corrects the timing of the bus clock signal in response to the input data, thereby generating a corrected clock signal for triggering the latch operation of the latch circuit 14. The corrected clock signal is supplied to the latch circuit 14 as the clock input CK.

The timing correction circuit 12 includes delay buffers 21 through 24, flip-flops 25 through 28 (delay length storing register), a comparison data storing register 29, a comparator 30, a decoder. 31, and a selector 32. The delay buffers 21 through 24 are connected in series. The first delay buffer 21 receives the bus clock signal supplied from the RAM control unit 11, and the bus clock signal is then successively delayed by the individual delay buffers. The outputs of the delay buffers 21 through 24 are supplied to the flip-flops 25 through 28 as delayed bus clock signals 1 through 4, respectively.

The input data supplied from the input buffer 13 is supplied to one input of the comparator 30. The other input of the comparator 30 receives data stored in the comparison data storing register 29. The comparator 30 changes its output to HIGH if the input data from the input buffer 13 matches the data from the comparison data storing register 29. The comparison data storing register 29 stores predetermined data, which is also stored in the semiconductor memory device 100 in advance at a predetermined address.

The predetermined address in the semiconductor memory device 100 may be an address for which the read timing is the slowest if there is variation in the data read timing depending on the addresses. If the data read timing is constant regardless of the addresses, any address usable for the purpose of correcting the clock of the semiconductor device 10 may be selected as the above-noted predetermined address.

The comparator 30 checks whether the input data from the input buffer 13, i.e., the read data retrieved from the semiconductor memory device 100, is the same as the expected data (i.e., the data stored in the comparison data storing register 29). The timing at which these two data items match is the timing at which the input data is received as the expected data. At the timing at which the two data items match, the comparator 30 changes its output to HIGH. Accordingly, the change of the output of the comparator 30 to HIGH can be suitably regarded as an indication of the timing at which the input data is correctly received.

The output of the comparator 30 is supplied to the clock input CK of the flip-flops 25 through 28. The flip-flops 25 through 28 respond to the positive transition of the clock input CK to latch the delayed bus clock signals 1 through 4, respectively. Since the positive transition of the clock input CK is the change to HIGH of the output of the comparator 30, each delayed bus clock signal is latched at the timing at which the input data is correctly received. As a result, the output signals of the flip-flops 25 through 28 serve as a timing indication signal indicative of the timing at which the input data is correctly received.

The decoder 31 receives and decodes the timing indication signal that is the outputs of the flip-flops 25 through 28. Through this decoding process, a clock signal that has the timing most suitable for latching the input data is selected from the bus clock signal and the delayed bus clock signals 1 through 4. The decoder 31 supplies the decoding result indicative of the optimal clock signal to the selector 32.

The selector 32 receives the bus clock signal and the delayed bus clock signals 1 through 4, and also receives the decoding result indicative of the optimal clock signal from the decoder 31. The selector 32 selects the optimal clock signal from the bus clock signal and the delayed bus clock signals 1 through 4 based on the decoding result, and outputs the selected optimal clock signal. The output clock signal is supplied to the latch circuit 14 as a corrected clock signal.

Thereafter, the latch circuit 14 latches the input data received through the input buffer 13 at the timing indicated by the corrected clock signal each time the read data from the semiconductor memory device 100 arrives at the semiconductor device 10. With this provision, it is possible to latch the input data at proper timing by letting the timing correction circuit 12 perform timing correction that absorbs the error and variation of the output timing of the semiconductor memory device 100 as well as the variation in the signal transmission paths between the semiconductor memory device 100 and the semiconductor device 10.

In this manner, the timing correction circuit 12 performs timing detection and correction by reading predetermined data from the predetermined address in the semiconductor memory device 100 when it is desired to carry out timing detection and correction. Once the delayed bus clock signals are latched in the flip-flops 25 through 28 of the timing correction circuit 12, the data stored in the flip-flops 25 through 28 stays unchanged. The corrected clock signal having the proper timing will then be used throughout subsequent memory read operations.

If the comparator 30 compares the input data with the stored content of the comparison data storing register 29 at all times, an accidental match between the read data and the content of the comparison data storing register 29 will result in the timing detection and correction by the timing correction circuit 12 being performed. In order to avoid this, the comparator 30 may be configured such that the activation/deactivation of the comparison operation is controllable by use of an enable signal. The enable signal is asserted when it is desired to conduct timing detection and correction, and is negated otherwise. This can prevent unnecessary timing detection and correction from being performed.

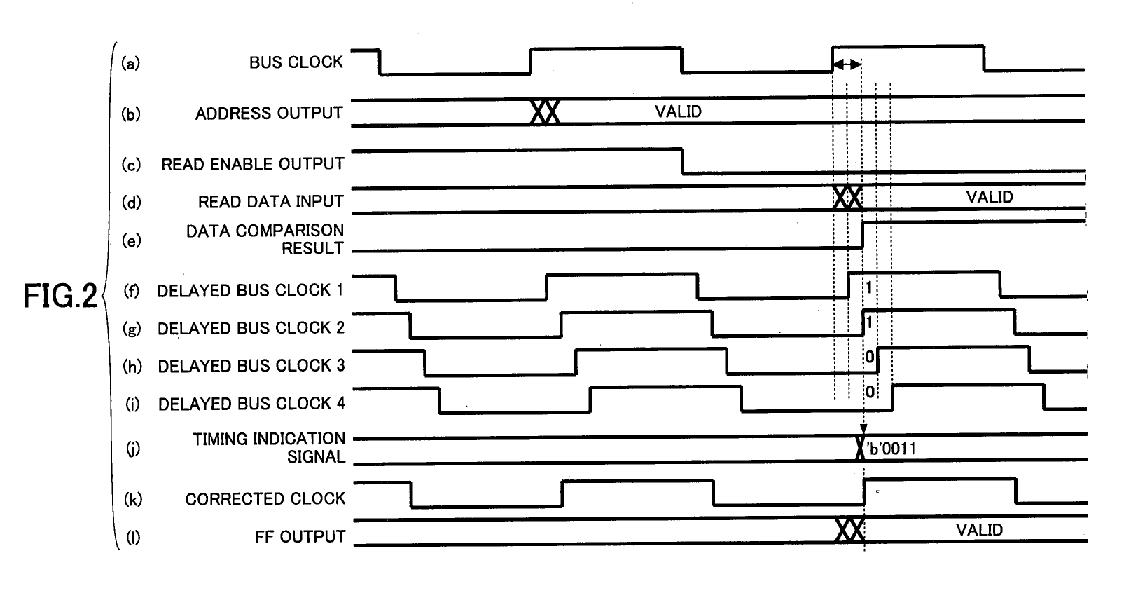

FIG. 2 is a timing chart for explaining the operation of the semiconductor device 10 of FIG. 1. In synchronization with the bus clock signal shown in (a), the RAM control unit 11 of the semiconductor device 10 outputs an address signal shown in (b), and asserts a read enable signal shown in (c) (assertion at LOW). In response, data is read from the semiconductor memory device 100, and is received by the input buffer 13 of the semiconductor device 10. The input buffer 13 supplies the input read data shown in (d) to the comparator 30 and the latch circuit 14. If the input read data matches the expected data, the comparator 30 changes its output signal, i.e., the data comparison result, to HIGH for signal assertion as shown in (e).

Letter designations (f) through (i) in FIG. 2 illustrate the delayed bus clocks 1 through 4 having respective, progressively increasing delays as they are delayed by the delay buffers 21 through 24. As shown in the illustrated example, the delayed bus clock 1 through the delayed bus clock 4 have progressively increasing delays in the order named, with the delayed bus clock 1 having the smallest delay and the delayed bus clock 4 having the largest delay. The delayed bus clocks 1 through 4 ((f) through (i) in FIG. 2) are latched by the flip-flops 25 through 28, respectively, at the timing corresponding to the positive transition of the data comparison result (FIG. 2 (e)). The stored contents of the flip-flops 25 through 28 are illustrated in (j) as a timing indication signal. In the example shown in FIG. 2, the delayed bus clocks 1 through 4 are HIGH, HIGH, LOW, and LOW, respectively, at the timing of the positive transition of the data comparison result. Accordingly, the timing indication signal is set to binary data “0011”.

As was described with reference to FIG. 1, the decoder 31 decodes the timing indication signal, thereby selecting a delayed bus clock signal having proper timing. In the example shown in FIG. 2, the delayed bus clock signal 2 shown in (g) is selected as the clock signal having the optimal timing. The selected clock signal is shown in (k) as a corrected clock signal.

The selection of a clock signal will be described more in detail. At the timing of the positive transition of the data comparison result, the delayed bus clocks 1 through 4 are HIGH, HIGH, LOW, and LOW, respectively. Namely, at the timing at which the correct input data is received, the delayed bus clock signals 1 and 2 have already risen whereas the delayed bus clock signals 3 and 4 have not yet risen. Since the latch circuit 14 latches input data at the positive transition of the clock input CK, the use of the delayed bus clock signal 3 or 4 as the clock input CK makes it possible to secure a sufficient setup time to latch the input data reliably. Here, the latch circuit 14 may have such circuit construction that proper data reading is possible if the clock input CK is provided at the same timing as the data input. In such a case, the input data is properly latched also by use of the delayed bus clock signal 2 as illustrated in the example.

If the timing of the clock signal for the latch purpose is excessively slow, it may give rise to a problem with the hold time. Accordingly, the delayed bus clock signal 2 and the delayed bus clock signal 3 that are situated immediately before and after the boundary between “0” and “1” in the timing indication signal “0011” are regarded as the clock signals having proper timing when considering both the setup time and the hold time. In the example shown in FIG. 2, the delayed bus clock signal 2 having earlier timing is selected as the clock having proper timing among the delayed bus clock signal 2 and the delayed bus clock signal 3.

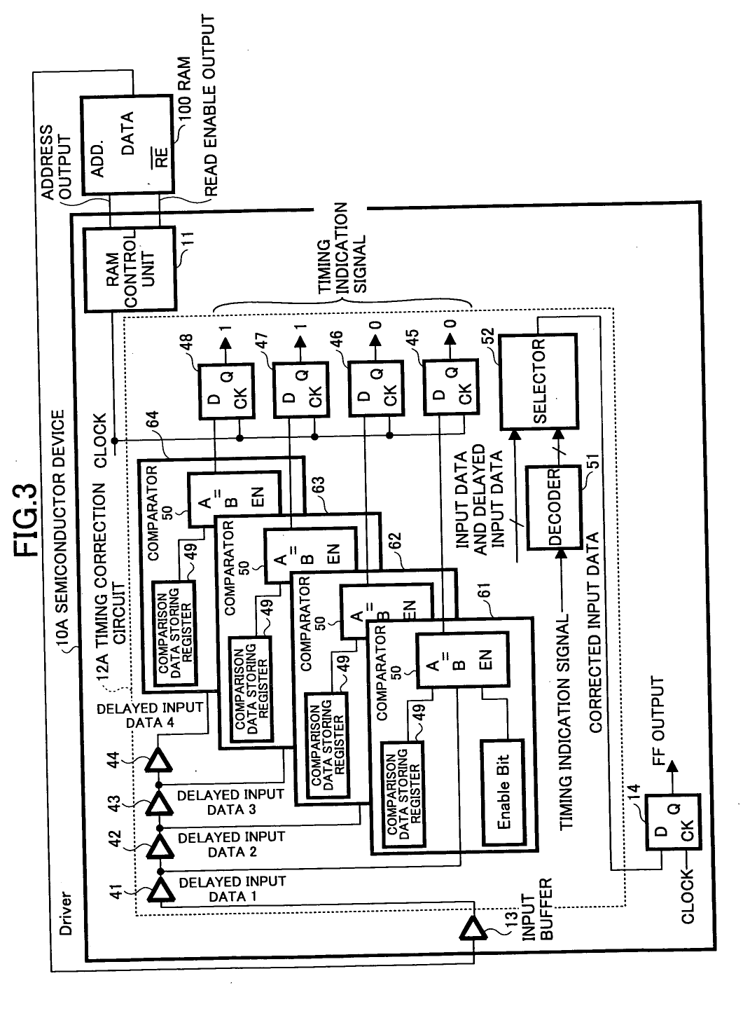

FIG. 3 is a block diagram showing a second embodiment of the semiconductor device according to the present invention. The configuration shown in FIG. 3 is designed for a CPU or a memory driver device such as a memory controller that receives data obtained by accessing a semiconductor memory device. It should be noted, however, that the present invention is applicable to any types of semiconductor devices as long as the devices are provided with the function to receive data in synchronization with a clock signal. In the first embodiment, timing was adjusted by focusing attention on the setup time. In the second embodiment, on the other hand, timing is adjusted by focusing attention on the hold time.

A semiconductor device 10A of FIG. 3 includes the RAM control unit 11, a timing correction circuit 12A, the input buffer 13, and the latch circuit 14. The semiconductor device 10A is connected to the semiconductor memory device (RAM) 100. The RAM control unit 11 of the semiconductor device 10A supplies an address signal and a read enable signal to the semiconductor memory device 100, thereby reading data from the address specified by the address signal. The read data is supplied to the input buffer 13 of the semiconductor device 10A through a data bus. The input buffer 13 supplies the received read data to the timing correction circuit 12.

The timing correction circuit 12 receives a clock signal supplied from the RAM control unit 11 and the input data (RAM read data) supplied from the input buffer 13. The timing correction circuit 12 corrects the timing of the input data in response to the relative timing relationship between the input data and the clock signal, thereby generating corrected input data. The corrected input data is supplied to the latch circuit 14. The latch circuit 14 may be comprised of flip-flops, which latch the data on a bit-by-bit basis in response to a clock input CK. The latch circuit 14 latches the corrected input data supplied from the timing correction circuit 12A by using the clock input CK that is the same clock signal that is supplied to the timing correction circuit 12A from the RAM control unit 11.

The timing correction circuit 12A includes delay buffers 41 through 44, flip-flops 45 through 48 (delay storing register), a decoder 51, a selector 52, and data comparison circuits 61 through 64. The data comparison circuits 61 through 64 all have the same construction, and include a comparison data storing register 49 and a comparator 50. The delay buffers 41 through 44 are connected in series. The first delay buffer 41 receives the input data supplied from the input buffer 13, and the input data is successively delayed by the individual delay buffers. The outputs of the delay buffers 41 through 44 are supplied to the data comparison circuits 61 through 64 as delayed input data 1 through 4, respectively.

In each of the data comparison circuits 61 through 64, the delayed input data is supplied to one input of the comparator 50. The other input of the comparator 50 receives data stored in the comparison data storing register 49. The comparator 50 changes its output to HIGH if the delayed input data matches the data from the comparison data storing register 49. The comparison data storing register 49 stores predetermined data, which is also stored in the semiconductor memory device 100 in advance at a predetermined address.

The comparator 50 checks whether the delayed input data is the same as the expected data (i.e., the data stored in the comparison data storing register 49). During the period in which the two compared data items match, the comparator 50 sets its output to HIGH. Accordingly, the period during which the comparison result signal output from the comparator 50 stays HIGH is regarded as the period in which the delayed input data is correct, i.e., regarded as the data valid period.

The comparison result signals that are the outputs of the comparators 50 of the data comparison circuits 61 through 64 are supplied to the data inputs D of the flip-flops 45 through 48, respectively. The clock inputs CK of the flip-flops 45 through 48 receive the clock signal from the RAM control unit 11. In response to the positive transition of the clock signal, the flip-flops 45 through 48 latch the comparison result signals supplied from the data comparison circuits 61 through 64, respectively. The comparison result signals supplied from the data comparison circuits 61 through 64 become HIGH only during the data valid periods of the delayed input data that have respective different delays. Thus, only in the flip-flops for which the clock input CK rises during the data valid periods, do the stored values become HIGH. As a result, the output signals of the flip-flops 45 through 48 serve as a timing indication signal indicative of the timing of the delayed input data that can be properly latched by the clock signal.

The decoder 51 receives and decodes the timing indication signal that is the outputs of the flip-flops 45 through 48. Through this decoding process, a data signal that has the most suitable timing as a target to be latched by the clock signal is selected from the input data and the delayed input data 1 through 4. The decoder 51 supplies the decoding result indicative of the optimal data signal to the selector 52.

The selector 52 receives the input data and the delayed input data 1 through 4, and also receives the decoding result indicative of the optimal data signal from the decoder 51. The selector 52 selects the optimal data signal from the input data and the delayed input data 1 through 4 based on the decoding result, and outputs the selected optimal data signal. The output data signal is supplied to the latch circuit 14 as a corrected input data.

Thereafter, the latch circuit 14 latches the corrected input data at the timing of the positive transition of the clock input CK after the input data is received through the input buffer 13 and corrected as to its timing by the timing correction circuit 12A each time the read data from the semiconductor memory device 100 arrives at the semiconductor device 10A. With this provision, it is possible to latch the input data at proper timing by letting the timing correction circuit 12A perform timing correction that absorbs the error and variation of the output timing of the semiconductor memory device 100 as well as the variation in the signal transmission paths between the semiconductor memory device 100 and the semiconductor device 10A.

As in the first embodiment, once the delayed input data are latched in the flip-flops 45 through 48 of the timing correction circuit 12A, the data stored in the flip-flops 45 through 48 stay unchanged. The corrected input data having the proper timing will then be used throughout subsequent memory read operations. Further, the comparators 50 in the data comparison circuits 61 through 64 are configured such that the activation/deactivation of the comparison operation is controllable by use of an enable signal. The enable signal is asserted when it is desired to conduct timing detection and correction, and is negated otherwise. This can prevent unnecessary timing detection and correction from being performed.

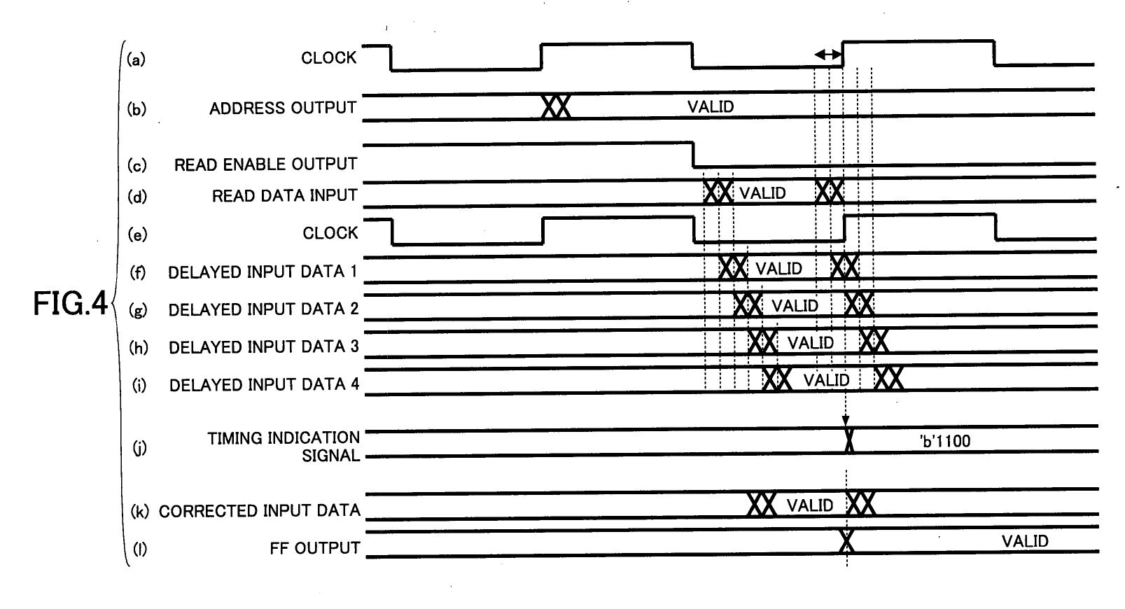

FIG. 4 is a timing chart for explaining the operation of the semiconductor device 10A of FIG. 3. In synchronization with the clock signal shown in (a), the RAM control unit 11 of the semiconductor device 10A outputs an address signal shown in (b), and asserts a read enable signal shown in (c) (assertion at LOW). In response, data is read from the semiconductor memory device 100, and is received by the input buffer 13 of the semiconductor device 10A. The input buffer 13 supplies the input read data shown in (d) to the timing correction circuit 12A.

Letter designations (f) through (i) in FIG. 4 illustrate the delayed input data 1 through 4 having respective, progressively increasing delays as they are delayed by the delay buffers 41 through 44. As shown in the illustrated example, the delayed input data 1 through the delayed input data 4 have progressively increasing delays in the order named, with the delayed input data 1 having the smallest delay and the delayed input data 4 having the largest delay. The delayed input data 1 through 4 ((f) through (i) in FIG. 4) are latched by the flip-flops 45 through 48, respectively, at the timing corresponding to the positive transition of the clock signal (FIG. 4 (e)). The stored contents of the flip-flops 45 through 48 are illustrated in (j) as a timing indication signal. In the example shown in FIG. 4, the delayed input data 1 through 4 are LOW, LOW, HIGH, and HIGH, respectively, at the timing of the positive transition of the clock signal. Accordingly, the timing indication signal is set to binary data “1100”.

As was described with reference to FIG. 3, the decoder 51 decodes the timing indication signal, thereby selecting delayed input data having proper timing. In the example shown in FIG. 4, the delayed input data signal 2 shown in (g) is selected as the data signal having the optimal timing. The selected data signal is shown in (k) as corrected input data.

The selection of a data signal will be described more in detail. At the timing of the positive transition of the clock signal, the delayed input data 1 through 4 are LOW, LOW, HIGH, and HIGH, respectively. Namely, at the timing at which the clock signal rises, the delayed input data 1 and 2 have already gone out of their data valid periods whereas the delayed input data 3 and 4 are still in their data valid periods. Since the latch circuit 14 latches input data at the positive transition of the clock input CK, the use of the delayed input data signal 3 or 4 as the input data makes it possible to secure a sufficient hold time to latch the input data reliably. Here, the latch circuit 14 may have such circuit construction that proper data reading is possible if the clock input CK is provided at the same timing as the end of the data valid period. In such a case, the input data is properly latched also by use of the delayed input data 2 as illustrated in the example.

If the timing of the data signal subject to latching is excessively slow, it may give rise to a problem with the setup time. Accordingly, the delayed input data 2 and the delayed input data 3 that are situated immediately before and after the boundary between “0” and “1” in the timing indication signal “1100” are regarded as the data signals having proper timing when considering both the setup time and the hold time. In the example shown in FIG. 4, the delayed input data 2 having earlier timing is selected as the data signal having proper timing among the delayed input data 2 and the delayed input data 3.

In the manner as described above, the present invention uses the timing correction circuit to correct the relative timing between the input data signal and the internal clock signal when the data arrives from another chip, thereby making it possible to latch the input data at proper timing. In so doing, a relative timing difference between the input data signal and the internal clock signal is progressively changed to generate a plurality of timing relationships, and an optimal timing relationship is selected in response to the result of latching operations using the plurality of timing relationships. This makes it possible to latch the input data under the condition that the relative timing between the input data signal and the internal clock signal is optimum. In so doing, the internal clock signal is relatively delayed to provide for a sufficient setup time, or is relatively advanced to provide for a sufficient hold time.

Further, the present invention is not limited to these embodiments, but various variations and modifications may be made without departing from the scope of the present invention.

The present application is based on Japanese priority application No. 2004-311422 filed on Oct. 26, 2004, with the Japanese Patent Office, the entire contents of which are hereby incorporated by reference.

What is claimed is:

1. A semiconductor device, comprising:
a timing correction circuit coupled to an external terminal for receiving an input data signal to change a relative timing between the input data signal and an internal clock signal to generate a plurality of relative latch timings to latch one of the input data signal and the internal clock signal in response to the other one of the input data signal and the internal clock signal, thereby selecting an optimal relative latch timing according to a result of the latching; and
a latch circuit coupled to said timing correction circuit to latch the input data signal with the optimal relative latch timing.

2. The semiconductor device as claimed in claim 1, wherein said timing correction circuit includes:
a delay circuit configured to receive the internal clock signal to output a plurality of delayed clock signals made by delaying the internal clock signal with progressively differing delays;
a delay storing register coupled to said delay circuit and the external terminal to latch the plurality of delayed clock signals at timing responsive to the input data signal; and
a selector circuit having inputs thereof coupled to said delay storing register, the internal clock signal, and the plurality of delayed clock signals to select and output one of the internal clock signal and the plurality of delayed clock signals in response to a content stored in said delay storing register,
wherein said latch circuit latches the input data signal at timing indicated by the selected clock signal output from said selector circuit.

3. The semiconductor device as claimed in claim 2, wherein said selector circuit selects and outputs as the selected clock signal a clock signal corresponding to a position of a boundary between 0 and 1 in the content stored in said delay storing register.

4. The semiconductor device as claimed in claim 2, wherein said selector circuit selects and outputs as the selected clock signal a clock signal having a minimum necessary setup time among the internal clock signal and the plurality of delayed clock signals.

5. The semiconductor device as claimed in claim 2, further comprising:
a comparison data storing register configured to store predetermined data;
a comparator coupled to said comparison data storing register and the external terminal to assert an output signal in response to a match between the predetermined data and the input data signal,
wherein said delay storing register latches the plurality of delayed clock signals in response to the output signal of said comparator.

6. The semiconductor device as claimed in claim 1, wherein said timing correction circuit includes:
a delay circuit configured to receive the input data signal to output a plurality of delayed data signals made by delaying the input data signal with progressively differing delays;
a delay storing register coupled to said delay circuit to latch the plurality of delayed data signals at timing responsive to the internal clock signal; and
a selector circuit having inputs thereof coupled to said delay storing register, the input data signal, and the plurality of delayed data signals to select and output one of the input data signal and the plurality of delayed data signals in response to a content stored in said delay storing register,
wherein said latch circuit latches the selected data signal output from said selector circuit at timing indicated by the internal clock signal.

7. The semiconductor device as claimed in claim 6, wherein said selector circuit selects and outputs as the selected data signal a data signal corresponding to a position of a boundary between 0 and 1 in the content stored in said delay storing register.

8. The semiconductor device as claimed in claim 6, wherein said selector circuit selects and outputs as the selected data signal a data signal having a minimum necessary hold time among the input data signal and the plurality of delayed data signals.

9. The semiconductor device as claimed in claim 6, further comprising:
a comparison data storing register configured to store predetermined data;
a comparator having a first input node coupled to said comparison data storing register and a second input node coupled to the external terminal to assert an output signal in response to a match between the predetermined data and a data signal of the second input node,
wherein said delay storing register has a data input thereof coupled to an output of said comparator.
